(19) United States
(12) Patent Application Publication
(10) Pub. No.: US 2013/0240829 A1
(43) Pub. Date: Sep. 19, 2013

(54) QUANTUM DOT STRUCTURE, METHOD FOR FORMING QUANTUM DOT STRUCTURE, WAVELENGTH CONVERSION ELEMENT, LIGHT-LIGHT CONVERSION DEVICE, AND PHOTOELECTRIC CONVERSION DEVICE

(71) Applicant: FUJIFILM CORPORATION, TOKYO (JP)

(72) Inventor: Teruhiko KURAMACHI, Ashigara-kami-gun (JP)

(73) Assignee: FUJIFILM CORPORATION, TOKYO (JP)

(21) Appl. No.: 13/886,458

(22) Filed: May 3, 2013

Related U.S. Application Data
(63) Continuation of application No. PCT/JP2011/074787, filed on Oct. 27, 2011.

(30) Foreign Application Priority Data
Nov. 4, 2010 (JP) 2010-247196

(51) Int. Cl. H01L 29/66; G02F 1/35; H01L 21/02

(52) U.S. Cl. CPC H01L 29/66977; H01L 21/02104; G02F 1/35
USPC 257/9; 438/478; 359/326

(57) ABSTRACT

This quantum dot structure has a matrix layer and a plurality of crystalline quantum dots provided spaced within the matrix layer. The quantum dots are provided at positions that differ in the direction of thickness of the matrix layer.

### BACKGROUND OF THE INVENTION

This invention relates to a quantum dot structure having crystalline quantum dots formed using a sputtering method, a method of forming the quantum dot structure, a wavelength conversion element, a light-light conversion device, and a photoelectric conversion device, and more particularly, to a quantum dot structure which is used for a solar cell, a photoelectric conversion device, a light-emitting device such as an LED, a photo-sensor of an infrared region or the like, a wavelength conversion element, and a light-light conversion device and a method of forming the quantum dot structure.

At the present time, studies of solar cells have been actively made. In a PN-junction solar cell in which a P-type semiconductor and an N-type semiconductor are joined and a PIN-junction solar cell in which a P-type semiconductor, an I-type semiconductor, and an N-type semiconductor are joined out of the solar cells, electrons are excited from a valence band to a conduction band by absorbing sunlight having energy equal to or more than a bandgap (Eg) between the conduction band and the valence band of the constituent semiconductors, holes are created in the valence band, and thus an electromotive force is generated in the solar cell.

The PN-junction solar cell and the PIN-junction solar cell have a single band gap and are called single-junction solar cells.

In the PN-junction solar cell and the PIN-junction solar cell, light having energy less than the bandgap is not absorbed but transmitted. On the other hand, energy more than the band gap is absorbed, but the energy component more than the bandgap in the absorbed energy is consumed as phonons, that is, as thermal energy. Accordingly, the single-junction solar cell having a single bandgap such as the PN-junction solar cell and the PIN-junction solar cell has a problem in that energy conversion efficiency thereof is poor.

In order to solve this problem, a multi-junction solar cell has been developed which can absorb light beams in a wide wavelength range and reduce loss to thermal energy to improve energy conversion efficiency by employing a structure in which plural PN or PIN junctions different in bandgap from each other are stacked and light beams are sequentially absorbed from the highest-energy beam.

However, in this multi-junction solar cell, since plural PN or PIN junctions are electrically joined in series, the output current is the minimum current generated by each junction. Accordingly, when a deflection occurs in a sunlight spectrum distribution and the output of one PN junction or PIN junction is lowered, there is a problem in that the outputs of the other PN junctions or PIN junctions not affected by the deflection in the sunlight spectrum distribution are also lowered and the overall output of the solar cell is materially lowered.

In order to solve this problem, a quantum dot solar cell employing a multi-quantum well structure in which semiconductor layers different in bandgap from each other are repeatedly stacked with a size (thickness) capable of obtaining a quantum confinement effect, has been proposed. In the quantum dot solar cell, wave functions between quantum dots are superimposed to form an intermediate band, thereby light beams of a wide wavelength range are absorbed, and loss as thermal energy is reduce to improve energy conversion efficiency (see PHYSICAL REVIEW LETTERS, 78, 5014 (1997), and APPLIED PHYSICS LETTERS, 93, 263105 (2008)).

PHYSICAL REVIEW LETTERS, 78, 5014 (1997), proposes a quantum dot solar cell in which quantum dots are made of two types of semiconductors different in bandgap from each other and a super-lattice structure is formed in which the quantum dots are regularly arranged such that bond occurs among the quantum dots having a three-dimensional confinement effect, and in which theoretical conversion efficiency thereof reaches 60% over the Shockley-Queisser limit by optimizing the bandgap combination of the constituent semiconductors.

APPLIED PHYSICS LETTERS, 93, 263105 (2008), discloses a quantum dot solar cell in which the size of the quantum dots are set to about dx=dy=dc≈4 nm so as to effectively use quantum effects.

PHYSICAL REVIEW LETTERS, 78, 5014 (1997), also discloses a method of forming quantum dots while allowing the quantum dots to hetero-epitaxially grow in a matrix semiconductor using a self-assembly method through the use of an MBE apparatus or an MOCVD apparatus, a structure in which the quantum dots are arranged in the matrix semiconductor, and the like.

However, in the above-mentioned method, since the quantum dots are formed due to a difference in lattice constant between a quantum dot material and a matrix material, the quantum dot size and the quantum dot arrangement exhibiting an ideal quantum confinement effect cannot be compatibly obtained. Accordingly, the quantum dot size and the quantum dot arrangement exhibiting the ideal quantum confinement effect are not compatible and thus satisfactory energy conversion efficiency cannot be obtained.

Moreover, the above-mentioned method requires a relatively expensive apparatus, and since a specific crystalline substrate is required in order to utilize the crystal lattice arrangement of a base substrate, there is a problem in that it is difficult to achieve an increase in area and to decrease the cost of the substrate. Accordingly, various methods have been proposed as the method of forming quantum dots (see JP 8-264825 A, JP 2007-535806 A, JP 2000-315653 A, and Thin Solid Films, 515 (2006), 1229-1249).

JP 8-264825 A discloses a method of forming quantum dots, in which quantum dots epitaxially grow in a state where the quantum dots are included in a matrix using a self-assembly method of forming a fine structure due to a lattice match difference.

JP 8-264825 A also discloses that three-dimensional growth, which is generally called Stranski-Krastanov (SK) mode growth and which can be observed in epitaxial growth of a lattice-mismatched system, is used to form GaAs quantum dots.

As a method in which restriction on a lattice mismatch ratio difference between a matrix material and a quantum dot material is removed to enhance a degree of freedom in selecting materials, and a film of large area and a high film formation speed can be achieved without using relatively expensive equipment such as the MBE apparatus or the MOCVD apparatus, JP 2007-535806 A discloses a method in which a photoelectric conversion film having an amorphous dielectric material as a matrix and having quantum dots of a crystalline semiconductor three-dimensionally uniformly distributed in the matrix is formed by alternately stacking plural stoichiometric dielectric material layers containing a compound of semiconductor material and dielectric layers having a high semiconductor composition ratio and heating the layers. This matrix serves as an energy barrier.

JP 2000-315653 A discloses a method of forming quantum dots of nitride semiconductors such as GaN, InN, AlN, InGaN, and AlGaN through the use of a droplet epitaxy method. In JP 2000-315653 A, it is stated that metal droplets are formed on a substrate by supplying a metal material for each layer and then quantum dots are formed to be matched with underlying lattices by heating the metal droplets while nitrifying the metal droplets using a nitrogen source. In JP 2000-315653 A, it is also stated that the heat treatment is performed at a high temperature of about 500° C. to 1500° C. so as to improve the crystal quality of the quantum dots.

In Thin Solid Films, 515 (2006), 1229-1249, it is stated by quoting previous papers that the shape of a thin film to be formed varies depending on film forming conditions such as a target-substrate (TS) distance, a target-substrate (TS) angle, a film forming pressure, a substrate bias, and a substrate temperature in a sputtering method. In Thin Solid Films, 515 (2006), 1229-1249, it is taught that amorphous structures can be formed discretely at a low temperature of a substrate, but amorphous structures are not likely to be discretely formed at a crystallization temperature of a substrate. It is also described that when a film is formed through the use of a reactive sputtering method using a Ti target and Ar/N₂ gas, the columnar structure of a TiN single-layered film varies depending on the flow rate of N₂ gas.

### SUMMARY OF THE INVENTION

Currently, in the method of forming quantum dots, there is a need for reducing a production cost by diverting a large-area process using a glass substrate already industrialized in the FPD (Flat Panel Display) or the like in which the process temperature is 500° C. or lower.

Accordingly, there is a need for three-dimensionally uniformly distributing quantum dots by using a semiconductor material such as InN having a bandgap of 1 eV or less in a bulk state, having a relatively low melting point, and being expected to be crystallized through a heating process at a relatively low temperature of 500° C. or lower.

However, the method proposed in JP 2007-535806 A in which a semiconductor rich material is crystallized and deposited in the matrix of an amorphous dielectric material by alternately stacking the stoichiometric layer and the dielectric layer having a high semiconductor composition ratio and heating the layers can be applied to a system in which crystalline quantum dots of an Si alloy are three-dimensionally uniformly distributed in a matrix material such as SiO₂, Si₃N₄, and SiC, but the method cannot be applied to a compound semiconductor material such as InN.

In the method of forming a photoelectric conversion film disclosed in JP 2007-535806 A, since the matrix layer and the quantum dots have to be made of the same semiconductor material and material selectivity is not allowed, an example where Si compound quantum dots are formed in the matrix material such as amorphous SiO₂, Si₃N₄, and SiC is described as an embodiment.

In the method of JP 2007-535806 A, when it is intended to change an Si compound to a crystalline semiconductor by annealing, at least a heating process at a temperature of 800° C. or higher for 30 minutes or more is required and thus it is required for the substrate to have a heat resistance of 800° C. or higher. Accordingly, it is difficult to use a substrate of non-alkali glass which is relatively cheap and which is used in the FPD or the like and to divert the process techniques used in the FPD or the like, and industrial development thereof have a lot of technical problems, thereby causing an increase in cost. As a result, there is a demand for a method of forming crystalline semiconductor quantum dots at a temperature of about 500° C. or lower at which the manufacturing techniques and the manufacturing equipment in the FPD or the like can be diverted.

In the method of forming quantum dots in JP 2000-315653 A, since a heat treatment is performed under boundary conditions in which the lattice arrangement of the substrate serves as a template at the bottom surface and the side surface and the top surface are not restricted, each quantum dot (QD) has a wide-based pyramid shape. Accordingly, the length of a base of the quantum dot is 20 nm or more and it is not likely to achieve a quantum confinement effect in the lateral direction well. Further, the gap between the quantum dots has to be set to a distance equal to or more than the quantum dot size so as not to join the quantum dots at the time of formation and it is thus difficult to achieve a resonant tunneling effect between the quantum dots.

In the method of JP 2000-315653 A, it is not possible to form crystalline semiconductor quantum dots having a diameter of 15 nm or less which are discretely and three-dimensionally uniformly distributed in the matrix material using a heat treatment at a relatively low temperature of 500° C. or less in a system in which the matrix layer and the quantum dot layer are made of different semiconductor materials, for example, in a system in which InN quantum dots are formed in a matrix material such as GaN or SiNy, by the use of the sputtering method allowing an increase in area and an increase in formation speed without using relatively expensive equipment.

In Thin Solid Films, 515 (2006), 1229-1249, even when a film is formed at a room temperature (low temperature) of a substrate through the use of a reactive sputtering method using an In target and an Ar/N₂ gas, fine unevenness of 10 to 20 nm can be formed, but a very thin InN layer with a thickness of 5 nm or less is formed in concave portions, and thus amorphous structures are not discretely formed.

The present invention was made to solve the above-mentioned problems based on the related art, and an object thereof is to provide a quantum dot structure in which quantum dots are arranged with a three-dimensionally uniform and periodic distribution and a method of forming a quantum dot structure which can form quantum dots with a three-dimensionally uniform and periodic distribution at a low production cost.

Another object of the present invention is to provide a wavelength conversion element, a light-light conversion device, and a photoelectric conversion device using the quantum dot structure.

To solve the above problems, a first aspect of the present invention provides a quantum dot structure forming method of forming crystalline quantum dots in a matrix layer on a substrate by supplying sputtering gas and reactant gas to a chamber in which the substrate and a target are disposed and performing a sputtering, wherein the matrix layer is made of a dielectric or a first nitride semiconductor, the quantum dots are made of a second nitride semiconductor, and the dielectric or the first nitride semiconductor and the second nitride semiconductor is different in composition from each other, the quantum dot structure forming method comprising the steps of: performing a sputtering using a constituent metal element of the second nitride semiconductor constituting the quantum dots as the target and using nitrogen gas as the reactant gas to periodically deposit particulates on the substrate with substantially the same size as the quantum dots in an amorphous state in which a nitrogen ratio is lower than a stoichiometric ratio; forming the matrix layer made of the dielectric or the first nitride semiconductor with a uniform thickness so as to cover the particulates, and alternately repeating the step of depositing the particulates and the step of forming the matrix layer to stack the matrix layer having the particulates therein and form a layered structure, and crystallizing the particulates to form the quantum dots by subjecting the layered structure to a heat treatment in an atmosphere of inert gas.

Preferably, in the step of forming the matrix layer, the surface of the matrix layer has a concavo-convex shape which reflects the shapes of the particulates and has a periodic unevenness with substantially the same size as the quantum dots, and particulates to be formed on the surface of the matrix layer are selectively formed at concave portions and convex portions of the concavo-convex shape.

Further, preferably, the particulates formed in the step of depositing the particulates are particulates of InNx having an atomic % ratio of In and N in a range of In:N=8:2 to In:N=65:35.

Further, preferably, the heat treatment of crystallizing the particulates to form the quantum dots is performed under conditions of an atmosphere of nitrogen-containing gas, a temperature of 500° C. or lower, and a retention time of 30 minutes or less.

Further, preferably, melting points of the dielectric or the first nitride semiconductor and the second nitride semiconductor satisfy the second nitride semiconductor<the dielectric or the first nitride semiconductor.

Further, preferably, melting points of the dielectric or the first nitride semiconductor and the second nitride semiconductor satisfy the second nitride semiconductor<500° C.<the dielectric or an alloy of the first nitride semiconductor and the second nitride semiconductor.

Preferably, the first nitride semiconductor constituting the matrix layer is GaN, SiNy, AlN, or InGaN.

A second aspect of the invention provides a quantum dot structure comprising: a matrix layer; and a plurality of crystalline quantum dots that are disposed discretely in the matrix layer, wherein the quantum dots are disposed at different positions in a thickness direction of the matrix layer.

Preferably, a plurality of the matrix layers are formed, a surface of an underlying matrix layer has a concavo-convex shape which reflects shapes of the quantum dots and has a periodic unevenness with substantially the same size as the quantum dots, and the quantum dots are selectively formed at concave portions and convex portions of the surface.

Further, for example, the matrix layer is made of a dielectric or a first nitride semiconductor, the quantum dots are made of a second nitride semiconductor, and the dielectric or the first nitride semiconductor and the second nitride semiconductor are different in composition from each other, and wherein melting points of the dielectric or the first nitride semiconductor and the second nitride semiconductor satisfy the second nitride semiconductor<the dielectric or the first nitride semiconductor.

Further, preferably, melting points of the dielectric or the first nitride semiconductor and the second nitride semiconductor satisfy the second nitride semiconductor<500° C.<the dielectric or an alloy of the first nitride semiconductor and the second nitride semiconductor.

Further, for example, the second nitride semiconductor constituting the quantum dots is InN, and the first nitride semiconductor constituting the matrix layer is GaN, SiNy, AlN, or InGaN.

A third aspect of the invention provides a wavelength conversion element including the quantum dot structure according to the first aspect and a wavelength conversion layer having a function of improving transmittance of an arbitrary wavelength range, wherein the quantum dots are made of a wavelength conversion composition that wavelength-converts absorbed light into light having energy lower than that of the absorbed light in a specific wavelength range of the absorbed light.

A fourth aspect of the invention provides a light-light conversion device, wherein the wavelength conversion element according to the third aspect is disposed on an incidence side of a photoelectric conversion layer, and wherein an effective refractive index of the wavelength conversion element is an intermediate refractive index between a refractive index of the photoelectric conversion layer and a refractive index of air.

A fifth aspect of the invention provides a photoelectric conversion device, wherein an N-type semiconductor layer is disposed on one side of a photoelectric conversion layer having the quantum dot structure according to the first aspect and a P-type semiconductor layer is disposed on the other side thereof, and wherein the quantum dots are three-dimensionally uniformly distributed and are arranged at regular intervals so as to superimpose a plurality of wave functions to form a miniband between the neighboring quantum dots.

According to the method of forming a quantum dot structure of the present invention, it is possible to form quantum dots having composition different from a matrix layer and having a three-dimensionally uniform and periodic distribution using a sputtering method. For example, according to the method of forming a quantum dot structure of the present invention, the quantum dots can be arranged in a staggered shape in the matrix layer. Accordingly, it is possible to three-dimensionally use quantum effects such as a quantum confinement effect and a resonant tunneling effect.

Since the melting point of the second nitride semiconductor is lower than 500° C., the heat treatment for crystallization can be performed at a relatively low temperature of 500° C. or lower. Accordingly, for example, the large-area process using a glass substrate already industrialized in the FPD or the like in which the process temperature is 500° C. or less can be used, thereby reducing the production cost.

In the quantum dot structure according to the present invention, since the quantum dots are arranged with a three-dimensionally uniform and periodic distribution, it is possible to three-dimensionally use quantum effects such as a quantum confinement effect and a resonant tunneling effect.

The quantum dot structure according to the present invention can be used in a solar cell, a photoelectric conversion device, a light-emitting device such as an LED, a photo-sensor of an infrared region or the like, a wavelength conversion element, and a light-light conversion device.

### BRIEF DESCRIPTION OF THE DRAWINGS

FIG. 1 is a cross-sectional view schematically illustrating a quantum dot structure according to an embodiment of the present invention.

FIGS. 2A to 2F are cross-sectional views schematically illustrating a method of forming a quantum dot structure shown in FIG. 1 in the order of steps.

FIG. 3A is a drawing-substituting photograph illustrating an example of a TEM image of a structure in which an InNx film and an SiNy film are formed on an Si substrate and FIG. 3B is a drawing-substituting photograph illustrating another example of the TEM image of the structure in which an InNx film and an SiNy film are formed on an Si substrate.

FIG. 4 is a drawing-substituting photograph illustrating a SEM image of a state where InNx is deposited in an amorphous state.

FIG. 5 is a drawing-substituting photograph illustrating a TEM image of a state where InNx is deposited in an amorphous state.

FIG. 6A is a perspective view schematically illustrating an observation direction of the structure in which InNx is deposited in an amorphous state and FIG. 6B is a drawing-substituting photograph illustrating an AFM image of a state where InNx is deposited in an amorphous state.

FIG. 7A is a drawing-substituting photograph illustrating a TEM image of InNx particulates before performing a heat treatment and FIG. 7B is a drawing-substituting photograph illustrating a TEM image of InNx particulates after performing a heat treatment.

FIG. 8A is a graph illustrating emission characteristics of a structure in which InNx quantum dots with an average particle diameter of 8 nm are formed in a matrix layer made of an SiNy film when it is PL-evaluated and FIG. 8B is a graph illustrating emission characteristics of a structure in which InNx quantum dots with an average particle diameter of 3 nm are formed in a matrix layer made of an SiNy film when it is PL-evaluated.

FIG. 9 is a cross-sectional view schematically illustrating a wavelength conversion element according to an embodiment of the present invention.

FIG. 10 is a diagram schematically illustrating a multi-exciton effect.

FIG. 11 is a diagram schematically illustrating a sunlight spectrum and a spectral sensitivity curve of a crystalline Si.

FIG. 12 is a graph illustrating a difference in reflectance due to a difference in configuration of an anti-reflection film.

FIG. 13 is a graph illustrating a relationship between the interval of quantum dots and the refractive index.

FIG. 14 is a graph illustrating reflectance of an SiO₂ film/a wavelength conversion element (Si quantum dots/SiO_{2Mat})/an Si substrate, where the wavelength conversion element has a refractive index of 1.80.

FIG. 15 is a graph illustrating reflectance of an SiO₂ film/a wavelength conversion element (Si quantum dots/SiO_{2Mat})/an Si substrate, where the wavelength conversion element has a refractive index of 2.35.

FIG. 16 is a graph illustrating a relationship between a difference in effective refractive index and an emission intensity in a wavelength conversion element.

FIG. 17A is a graph illustrating a relationship between uniformity of quantum dots and an emission intensity in a wavelength conversion element, FIG. 17B is a drawing-substituting photograph illustrating a TEM image of a structure having non-uniform quantum dots, and FIG. 17C is a drawing-substituting photograph illustrating a TEM image of a structure having uniform quantum dots.

FIG. 18 is a cross-sectional view schematically illustrating a photoelectric conversion device having the wavelength conversion element according to an embodiment of the present invention.

FIG. 19 is a cross-sectional view schematically illustrating a configuration of another photoelectric conversion device according to an embodiment of the present invention.

FIG. 20A is a drawing-substituting photograph illustrating an example of a TEM image of a structure in which InNx particulates are formed in a matrix layer made of an SiNy film and FIG. 20B is a drawing-substituting photograph illustrating another example of the TEM image of the structure in which InNx particulates are formed in a matrix layer made of an SiNy film.

FIG. 21 is a drawing-substituting photograph illustrating an example of a TEM image of a structure in which InNx quantum dots are formed in a matrix layer made of an SiNy film.

### DETAILED DESCRIPTION OF THE INVENTION

Hereinafter, a quantum dot structure, a quantum dot structure forming method, a wavelength conversion element, a light-light conversion device, and a photoelectric conversion device according to the present invention will be described in detail with reference to exemplary embodiments shown in the accompanying drawings.

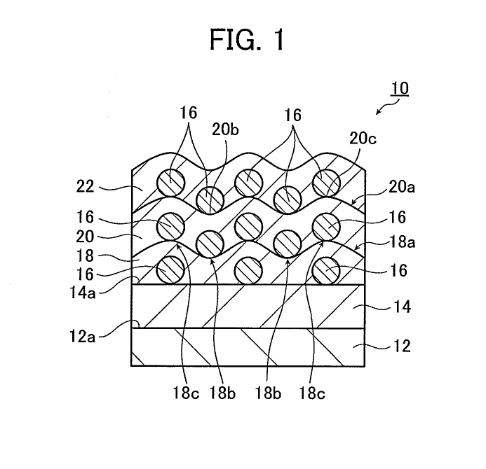

FIG. 1 is a cross-sectional view schematically illustrating a quantum dot structure according to an embodiment of the present invention.

In the quantum dot structure 10 shown in FIG. 1, for example, four layers of a first matrix layer 14 to a fourth matrix layer 22 are stacked, and plural quantum dots 16 are independently arranged to be separated from each other in the second matrix layer 18 to the fourth matrix layer 22.

In the quantum dot structure 10, the first matrix layer 14 is formed on the surface 12a of the substrate 12. The surface 14a of the first matrix layer 14 is flat. Plural quantum dots 16 are discretely and periodically arranged on the surface 14a of the first matrix layer 14.

The first matrix layer 14 to the fourth matrix layer 22 of the quantum dot structure 10 are collectively simply referred to as a matrix layer.

The second matrix layer 18 is formed on the surface 14a of the first matrix layer 14 so as to cover the quantum dots 16. The second matrix layer 18 reflects the shape and the arrangement state of the quantum dots 16 and the surface 18a has a periodic concavo-convex shape, whereby a convex portion 18c and a concave portion 18b are regularly formed. The convex portions 18c and the concave portions 18b forming the concavo-convex shape have substantially the same scale as the quantum dots 16.

The quantum dots 16 are arranged on the surface 18a of the second matrix layer 18. In this case, the quantum dots 16 are formed in the concave portions 18b and the convex portions 18c of the surface 18a of the second matrix layer 18, and the quantum dots 16 are discretely and regularly arranged.

The third matrix layer 20 is formed on the surface 18a of the second matrix layer 18 so as to cover the quantum dots 16. The surface 20a of the third matrix layer 20 also reflects the shape of the quantum dots 16 and the surface 20a has a periodic concavo-convex shape.

The quantum dots 16 are formed in the concave portions 20b and the convex portions 20c of the surface 20a of the third matrix layer 20. The quantum dots 16 are discretely and regularly arranged.

The fourth matrix layer 22 is formed on the surface 20a of the third matrix layer 20 so as to cover the quantum dots 16. The surface 22a of the fourth matrix layer 22 also reflects the shape of the quantum dots 16, and the surface 22a has a periodic concavo-convex shape.

In the quantum dot structure 10, the quantum dots 16 are discretely arranged at the convex portions and the concave portions of the surface of the underlying matrix layer in the second or subsequent layers, and the arrangement positions thereof are different in the thickness direction (hereinafter, also referred to as a vertical direction) of the matrix layer in a single matrix layer. In addition, since the convex portions and the concave portions are periodically formed, the quantum dots 16 are also periodically arranged in the lateral direction perpendicular to the vertical direction. Accordingly, the quantum dots 16 can be arranged in a staggered shape. The quantum dots 16 are periodically and regularly arranged in the lateral direction in the first layer.

The quantum dot structure 10 according to this embodiment has four matrix layers, but the number of matrix layers stacked is not particularly limited, and at least one matrix layer containing the quantum dots 16 is present.

The quantum dot structure 10 is provided with the first matrix layer 14, but the quantum dots 16 may be formed directly on the surface 12a of the substrate 12 without forming the first matrix layer 14.

In this embodiment, the first matrix layer 14 to the fourth matrix layer 22 are made of an amorphous nitride semiconductor. For example, GaN, SiNy, AlN, and InGaN are used as the nitride semiconductor. The first matrix layer 14 to the fourth matrix layer 22 may be made of a dielectric material, as long as it is amorphous.

The quantum dots 16 are made of a crystalline nitride semiconductor. The nitride semiconductor is, for example, an InN compound. It is preferable that the material constituting the quantum dots has a bandgap of 1 eV or less in a bulk state.

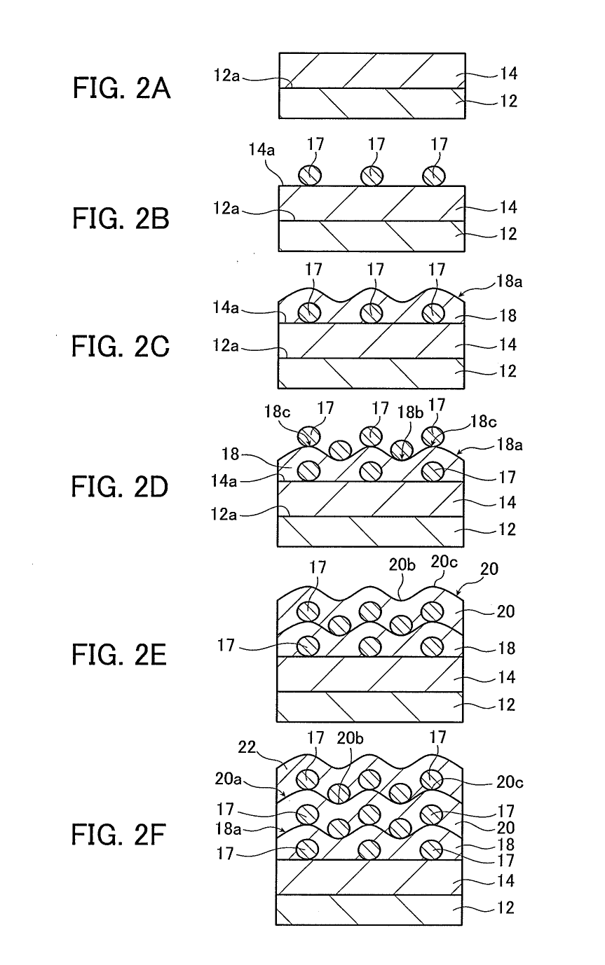

It is known that sunlight has a wide energy distribution. In order to efficiently absorb the energy of sunlight, an intermediate band layer (IB layer) is formed between the bandgaps (Eg) of the quantum dot and the matrix layer at the time of designing a PIN-junction quantum dot solar cell. It is theoretically proposed that a specific relationship is established between band energy positions of an IB (Intermediate band), a CB (Conduction Band), and a VB (Valence Band) and the theoretical conversion efficiency in the PIN-junction quantum dot solar cell (see PHYSICAL REVIEW LETTERS, 78, 5014 (1997) FIGS. 1 and 2, and PHYSICAL REVIEW LETTERS, 97, pp. 247701-4 (2006)). According to this proposal, it is preferable that the bandgap of the intermediate band be 1.0 to 1.8 eV and the bandgap of the matrix be 1.5 to 3.5 eV.

According to APPLIED PHYSICS LETTERS, 93, 263105 (2008), it is thought that the quantum dot size is preferably about 4 nm. When the quantum dot size is reduced, the bandgap becomes larger than the bandgap in the bulk state due to the quantum effect. When the quantum dot size is set to about 4 nm, the bandgap becomes larger by about 0.2 to 0.7 eV than the bandgap in the bulk state, though it varies depending on the band structure. For this reason, it is preferable that the material constituting the quantum dot has a bandgap of 1 eV or less in a bulk state.

It is preferable that the material constituting the matrix layer has a bandgap of 1.5 to 3.5 eV in a bulk state. Preferably, InGaN can be used as the material having a bandgap of 1.5 to 3.5 eV.

The size of the quantum dots 16 is, for example, 15 nm or less in diameter. Accordingly, in the second matrix layer 18 to the fourth matrix layer 22 having a concavo-convex surface reflecting the shape of the quantum dots 16, it is preferable that the convex portions have a semispherical shape of 15 nm or less and the interval of the convex portions is 15 nm or less.

For example, a Si substrate is used as the substrate 12, but the substrate 12 is not limited to the Si substrate.

In this embodiment, in a single matrix layer, the quantum dots 16 can be arranged at different positions in the vertical direction. Accordingly, compared with a layer-by-layer method according to the related art, it is possible to enhance a degree of freedom in arrangement of the quantum dots 16 and to three-dimensionally use quantum effects such as a quantum confinement effect and a resonant tunneling effect.

Next, a method of forming the quantum dot structure 10 shown in FIG. 1 will be described below.

FIGS. 2A to 2F are cross-sectional views schematically illustrating the method of forming the quantum dot structure shown in FIG. 1 in the order of steps. The method of forming the quantum dot structure 10 will be described with reference to an example where a Si substrate is used as the substrate 12, SiNy is used for the matrix layers, and a crystalline InN compound is used for the quantum dots 16.

First, in order to form the first matrix layer 14 on the surface 12a of the substrate 12, the substrate 12 is set into a vacuum chamber not shown. Regarding the film forming conditions, for example, a target (not shown) made of Si₃N₄ is used, argon gas is used as the sputtering gas, nitrogen gas is used as the reactant gas, and the temperature of the substrate 12 is set to, for example, a room temperature. Under these film forming conditions, as shown in FIG. 2A, the first matrix layer 14 with a thickness of, for example, 20 nm is formed on the surface 12a of the substrate 12 through the use of an RF sputtering method.

In this case, sputtered particles are deposited on the surface 12a of the substrate 12 at a nitrogen ratio equal to or more than the stoichiometric ratio with a uniform thickness using an amorphous material of a stoichiometric ratio as the target and using the nitrogen gas as the reactant gas. As a result, the first matrix layer 14 with a uniform thickness is formed.

When the matrix layer is formed of a SiNy film, Si₃N₄ is used as the amorphous material of a stoichiometric ratio.

Then, in order to form the quantum dots 16, a constituent metal element of the nitride semiconductor constituting the quantum dots 16 is used as a source material, that is, the constituent metal element is used as the target. The constituent metal is, for example, In obtained by excluding nitrogen from InN, when the quantum dots are made of InN.

In this case, regarding the film forming conditions, for example, a target (not shown) made of In is used, argon gas is used as the sputtering gas, nitrogen gas is used as the reactant gas, and the temperature of the substrate 12 is set to, for example, a room temperature. Under these film forming conditions, the sputtered particles of In are radiated to the surface 14a of the first matrix layer 14 so as to have a thickness of, for example, 10 nm, using a sputtering method.

The sputtered particles of In are deposited as an amorphous nitride, the nitrogen ratio of which is smaller than the stoichiometric ratio, on the surface 14a of the first matrix layer 14 using the nitrogen gas as the reactant gas. At this time, as shown in FIG. 2B, the amorphous nitride is periodically deposited in a particle shape, whereby particle-like particulates 17 to be the quantum dots 16 are periodically formed on the surface 14a of the first matrix layer 14. The particulates 17 have, for example, a semispherical shape, because the surface energy is the minimum.

The composition of the amorphous nitride constituting the particulates 17 is InNx (where 1>x). In InNx, the ratio of atomic % of the In and N is preferably in a range of 8:2 to 65:35.

Then, as shown in FIG. 2C, the second matrix layer 18 is formed, for example, with a thickness of 20 nm on the surface 14a of the first matrix layer 14 so as to cover the particle-like particulates 17 to be the quantum dots 16. Since the second matrix layer 18 is formed in the same way as forming the first matrix layer 14, detailed description thereof will not be repeated.

Since the second matrix layer 18 covers the particle-like particulates 17, the surface 18a thereof reflects the shape and the arrangement state of the particle-like particulates 17 and has a concavo-convex shape. The convex portions 18c and the concave portions 18b forming the concavo-convex shape have substantially the same scale as the particulates 17, that is, the quantum dots 16.

Then, as shown in FIG. 2D, the particulates 17 to be the quantum dots 16 are formed on the surface 18a of the second matrix layer 18. Since the particulates 17 are formed in the same way as forming the particulates 17 in the first layer, detailed description thereof will not be repeated.

At this time, the particulates 17 are deposited at the concave portions 18b having low surface energy in the surface 18a of the second matrix layer 18 and are also deposited in the convex portions 18c due to a shadow effect. In this way, the particulates 17 are selectively formed at the concave portions 18b and the convex portions 18c of the surface 18a. Accordingly, in a single matrix layer, the particulates 17 are arranged at different positions in the vertical direction.

Then, as shown in FIG. 2E, the third matrix layer 20 is formed, for example, with a thickness of 20 nm on the surface 18a of the second matrix layer 18 so as to cover the particulates 17. Since the third matrix layer 20 is formed in the same way as forming the first matrix layer 14, detailed description thereof will not be repeated.

Since the third matrix layer 20 covers the particle-like particulates 17, the surface 20a thereof reflects the shape of the particle-like particulates 17 and has a concavo-convex shape, similarly to the second matrix layer 18. The concavo-convex shape has substantially the same scale as the particulates 17, that is, the quantum dots 16.

Then, as shown in FIG. 2F, the particulates 17 to be the quantum dots 16 are selectively formed at the concave portions 20b and the convex portions 20c on the surface 20a of the third matrix layer 20 as described above.

Thereafter, the fourth matrix layer 22 is formed, for example, with a thickness of 20 nm on the surface 20a of the third matrix layer 20 so as to cover the particulates 17. Since the fourth matrix layer 22 is formed in the same way as forming the first matrix layer 14, detailed description thereof will not be repeated.

Then, for example, in an atmosphere of nitrogen in which nitrogen gas (N₂ gas) normally flows at 1 sccm, a heat treatment is performed, for example, at a temperature of 400° C. for 15 minutes. By this heat treatment, the particulates 17 are nitrified and crystallized to form crystallized InN from the amorphous nitride, and the shape of the particulates 17 change to a spherical shape, whereby the quantum dots 16 made of crystalline InN, for example, with a diameter of 15 nm or less are formed.

The heat treatment is not limited to use the nitrogen gas (N₂ gas) as long as an atmosphere of inert gas such as an atmosphere of nitrogen-containing gas or an atmosphere of nitrogen can be obtained, and may be performed in an atmosphere of nitrogen gas containing NH₃.

The conditions of the heat treatment temperature and the retention time (heat treatment time) are not particularly limited as long as the conditions of a temperature of 500° C. or lower and a retention time of 30 minutes or less, and the temperature is equal to or lower than the melting point of the matrix layer and the particulates 17. Preferably, the conditions of the heat treatment temperature and the retention time (heat treatment time) are 500° C. or lower and 1 minute or less. In the present invention, the heat treatment temperature means a temperature of the substrate 12 such as an Si substrate at the time of performing the heat treatment.

In this embodiment, the crystalline quantum dots 16 with a diameter of 15 nm or less can be formed through a heat treatment of relatively low temperature, that is, at a temperature of 500° C. or lower for a retention time of 30 minutes or less. Accordingly, the large-area process using a glass substrate already industrialized in the FPD or like in which the process temperature is equal to or lower than 500° C. can be used, thereby reducing the production cost.

In this embodiment, the particulates 17 can be formed in a three-dimensionally uniform and periodic distribution. Accordingly, since the distribution of the quantum dots 16 in the matrix layer is uniform and periodic in the vertical direction and the lateral direction, it is possible to three-dimensionally use quantum effects such as a quantum confinement effect and a resonant tunneling effect.

In this embodiment, the quantum dots 16 can be formed at different positions in the vertical direction in a single matrix layer. Accordingly, compared with a layer-by-layer method according to the related art, it is possible to form the quantum dots 16 with a higher degree of freedom.

In the formation method according to this embodiment, SiNy is used for the matrix layer, but the matrix layer is not limited to SiNy, and GaN, InGaN, AlN, and the like can be used for the matrix layer.

The RF sputtering method is used to form the matrix layers, but the present invention is not limited thereto, and an ALD (Atomic Layer Deposition) method may be used.

It is preferable that the temperature of the substrate be 100° C. or lower when forming the matrix layers and the particulates 17.

In this embodiment, the dielectric or the nitride semiconductor constituting the matrix layers and the nitride semiconductor constituting the quantum dots 16 are different from each other in composition. In the matrix layers and the quantum dots, the melting points of the dielectric or the nitride semiconductor constituting the matrix layers and the nitride semiconductor constituting the quantum dots 16 satisfy the nitride semiconductor (the second nitride semiconductor) constituting the quantum dots 16<the dielectric or the nitride semiconductor (the first nitride semiconductor) constituting the matrix layers, and also satisfy the nitride semiconductor constituting the quantum dots 16<500° C.<the dielectric or an alloy of the nitride semiconductor constituting the matrix layers and the nitride semiconductor constituting the quantum dots 16.

Accordingly, only the particulates can be preferentially melted and crystallized at the time of performing a heat treatment such as annealing. By setting the melting point of the particulates 17 to be lower than 500° C., it is possible to suppress a semiconductor produced by alloying the dielectric or the nitride semiconductor constituting the matrix layers and the nitride semiconductor constituting the quantum dots 16 and to melt and crystallize only the particulates 17.

By setting the particulates 17 to the amorphous state and setting the nitrogen ratio to be lower than the stoichiometric ratio, the melting point can be made to be lower than 500° C.

The inventor of the present invention confirmed that a matrix layer made of a SiNy film can be uniformly formed by radiating sputtered particles of an amorphous semiconductor into nitrogen plasma through the use of a reactive sputtering method using an amorphous semiconductor of a stoichiometric ratio as a source material, that is, using the amorphous semiconductor of a stoichiometric ratio as a target, and using nitrogen gas.

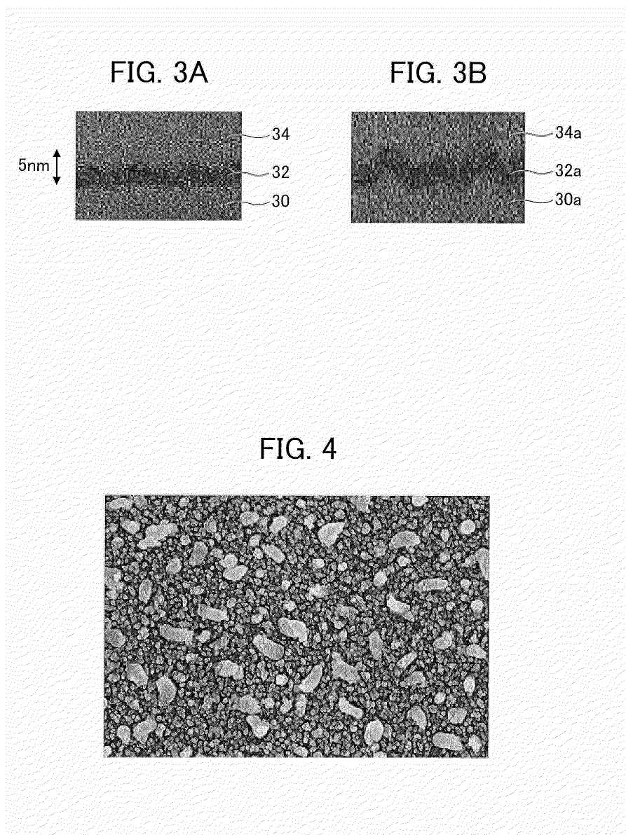

In this case, as shown in FIG. 3A, it was confirmed by forming an InNx film 32/an SiNy film 34 on a flat Si substrate 30. As a result, as shown in FIG. 3A, the SiNy film 34 becomes a flat film with a constant thickness if the underlying InNx film 32 is flat.

Regarding the conditions for forming the SiNy film, Si₃N₄ was used as a target, an ultimate vacuum was set to 3×10⁻⁴ Pa or less, the substrate temperature is set to an RT (Room Temperature), the input power was set to 100 W, the film forming pressure was set to 0.3 Pa, the flow rate of argon gas as the sputtering gas was set to 15 sccm, and the flow rate of nitrogen gas as the reactant gas was set to 5 sccm.

On the other hand, regarding the conditions for forming the InN film, an amorphous semiconductor of a stoichiometric ratio was used as a source material, that is, InN was used as a target, an ultimate vacuum was set to 3×10⁻⁴ Pa or less, the substrate temperature was set to 400° C., the input power was set to 50 W, the film forming pressure was set to 0.1 Pa, the flow rate of argon gas as the sputtering gas was set to 1 sccm, and the flow rate of nitrogen gas as the reactant gas was set to 7 sccm.

It was also confirmed by forming an InNx film 32a and an SiNy film 34a on an Si substrate 30a having unevenness.

As shown in FIG. 3B, the InNx film 32a reflected the unevenness of the underlying Si substrate 30a to be a concavo-convex film. The SiNy film 34a followed the InNx film 32a to be a concavo-convex film with a uniform thickness. The conditions for forming the InNx film 32a and the SiNy film 34a were the same as the above-mentioned conditions for forming the InNx film 32 and the SiNy film 34.

In this way, the SiNy film to be a matrix layer becomes a film with a uniform thickness reflecting the surface shape of the underlying layer. Accordingly, the surface of the matrix layer has a concavo-convex shape reflecting the shape of the particulates 17 to be the quantum dots 16.

In addition, the inventor of the present invention confirmed that the nitride semiconductor can be deposited in a particle shape by radiating the sputtering particles of a constituent metal element of the nitride semiconductor constituting the quantum dots 16 into nitrogen plasma to deposit the sputtered particle as an amorphous nitride through the use of a reactive sputtering method using the constituent metal element as a source material, that is, using the constituent metal element as a target, and using nitrogen gas.

For example, when the quantum dots are made of InN, the constituent metal element is In obtained by excluding nitrogen from InN.

Regarding the conditions for forming the InN film, In was used as a target, an ultimate vacuum was set to 3×10⁻⁴ Pa or less, the substrate temperature is set to an RT, the input power was set to 30 W, the film forming pressure was set to 0.1 Pa, the flow rate of argon gas as the sputtering gas was set to 3 sccm, and the flow rate of nitrogen gas as the reactant gas was set to 5 sccm.

When the InNx film is deposited as a single layer with a thickness of 100 nm under the above-mentioned conditions, particle-like InNx particulates were deposited as shown in FIG. 4. As the EDX analysis result on the InNx particulates, the In:N ratio of InNx was 8:2 to 65:35 in terms of atomic % ratio.

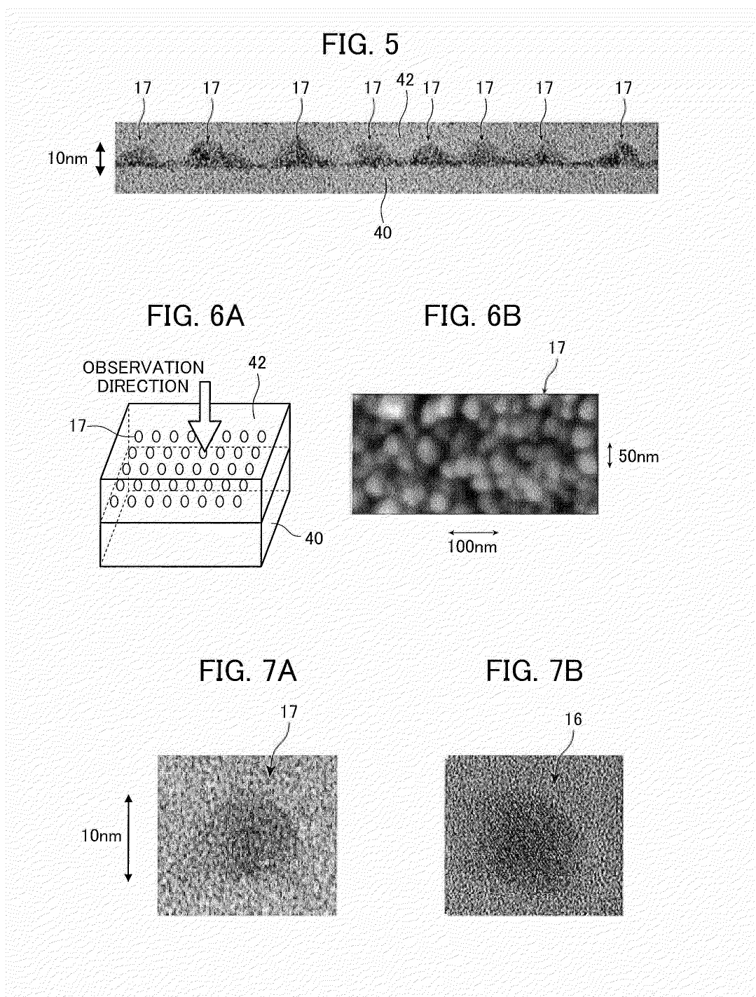

Moreover, the inventor of the present invention formed an InNx film on the Si substrate 40 as shown in FIG. 5 and confirmed that semispherical particulates 17 were formed periodically. In FIG. 5, a SiNy film 42 was formed to cover the particulates 17.

FIG. 6A is a perspective view schematically illustrating a film structure shown in FIG. 5 and schematically illustrating an observation direction of a structure in which InNx is deposited in an amorphous nitride state. As shown in FIG. 6A, the particulates 17 of InNx were observed from the SiNy film 42 using an AFM. The result is shown in FIG. 6B.

As shown in the AFM image of FIG. 6B, the particulates 17 of InNx have a semispherical shape. This is because the surface energy of the particulates 17 of InNx is the minimum.

A heat treatment was performed in an atmosphere of nitrogen at a temperature of 400° C. for 15 minutes after forming the particulates 17 of InNx as shown in FIG. 5. As a result, though a lattice image was not observed from the particulates 17 of InNx shown in FIG. 7A before performing the heat treatment, a lattice image was observed from FIG. 7B after performing the heat treatment, from which it was confirmed that the particulates 17 are crystallized to be the quantum dots 16 of InN through the heat treatment. Further, the shape was changed to a spherical shape through the heat treatment, whereby spherical quantum dots were obtained.

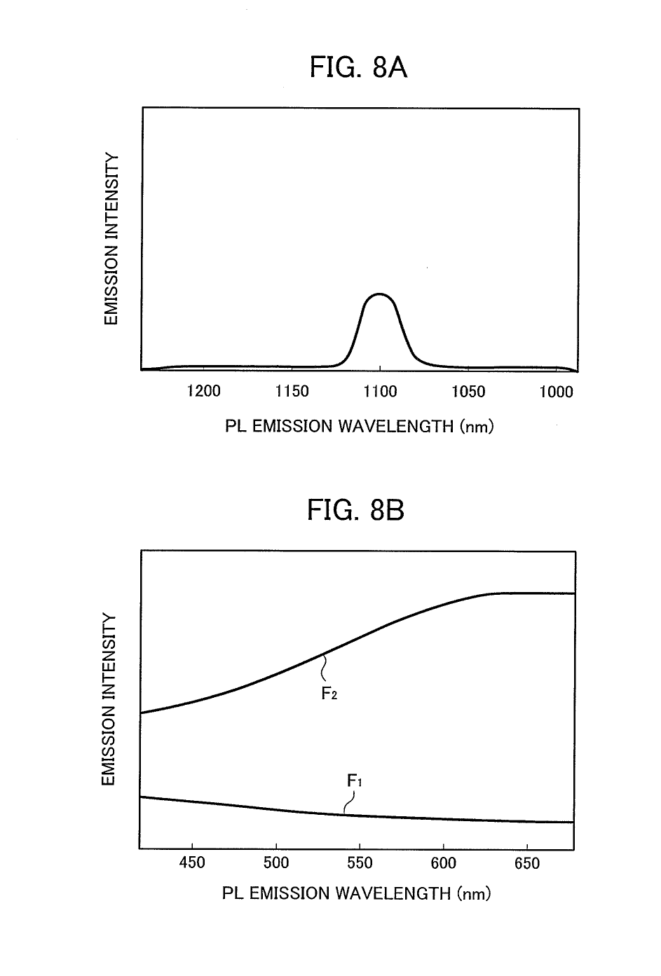

The obtained quantum dots 16 were fluorescence-evaluated. Specifically, quantum dots 16 (InN quantum dots) having different particle diameters were produced and the PL emission thereof was measured. The result is shown in FIGS. 8A and 8B. FIG. 8A shows emission characteristics of the PL emission of the InN quantum dots with an average particle diameter of 8 nm. In the case of the InN quantum dots with an average particle diameter of 8 nm, the particle diameters were in a range of 6 to 10 nm. The emission characteristics of the PL emission shown in FIG. 8A were obtained by irradiating light with an excitation wavelength of 355 nm.

FIG. 8B shows the emission characteristics of the PL emission of the InN quantum dots with an average particle diameter of 3 nm. In the case of the InN quantum dots with an average particle diameter of 3 nm, the particle diameters were in a range of 2 to 4 nm. The emission characteristics of the PL emission shown in FIG. 8B were obtained by irradiating light with an excitation wavelength of 380 nm.

As shown in FIG. 8A, in the quantum dots 16 (InN quantum dots) with an average diameter of 8 nm, light emission (infrared light emission) in the vicinity of a wavelength of 1100 nm was observed from the quantum dots crystallized through annealing. On the other hand, light emission was not observed from the quantum dots not annealed, and therefore, the illustration of the emission characteristics thereof is omitted.

As shown in FIG. 8B, in the quantum dots 16 (InN quantum dots) with an average diameter of 3 nm, the emission intensity of the quantum dots crystallized through annealing at 475° C. (reference sign F₂ in FIG. 8B) was higher than the emission intensity of the quantum dots not annealed (reference sign F₁ in FIG. 8B), and light emission in the vicinity of 600 nm was observed. Light emission due to the quantum dots 16 was not observed with respect to the quantum dots not annealed (reference sign F₁ in FIG. 8B).

The above-mentioned quantum dot structure 10 has a wavelength conversion function and can be used alone as a wavelength conversion film. Further, the quantum dot structure 10 can be used, for example, for a wavelength conversion element, a wavelength conversion device, and a solar cell.

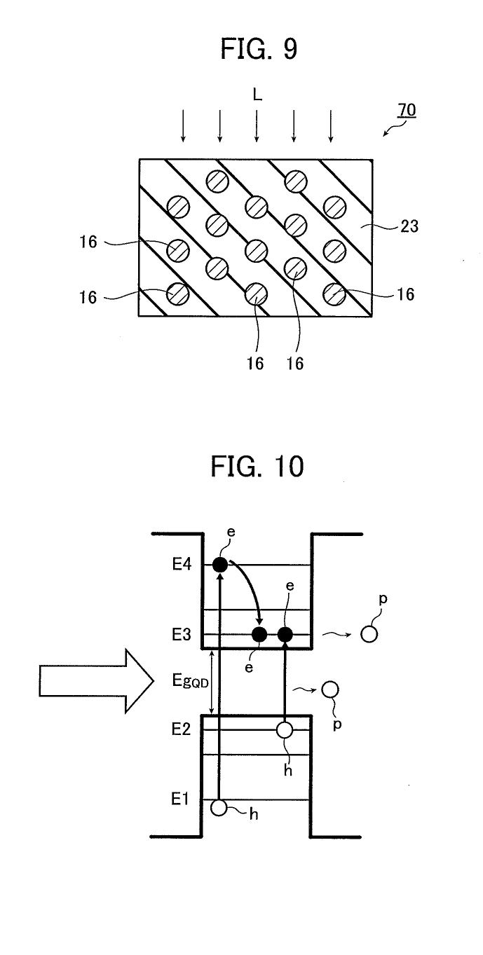

The wavelength conversion element 70 shown in FIG. 9 has the same configuration as the quantum dot structure 10 according to the above-mentioned embodiment. In the wavelength conversion element 70, quantum dots 16 are arranged in a staggered shape in a matrix layer 23. The matrix layer 23 has the same configuration as the first matrix layer 14 to the fourth matrix layer 22 of the quantum dot structure 10 and thus detailed description thereof will not be repeated.

In the wavelength conversion element 70, the number of quantum-dot layers in the quantum dot structure 10 is not particularly limited.

The wavelength conversion element 70 has a function of absorbing incident light L and wavelength-converting the absorbed light into light having energy lower than that of the absorbed light in a specific wavelength range of the absorbed light (hereinafter, referred to as a wavelength conversion function) and a function of confining the incident light L (hereinafter, referred to as a light confinement function).

In the wavelength conversion element 70, the wavelength conversion function is specifically a down-conversion function. The down-conversion function is based on an effect of generating one or more photons for each absorbed photon, which is called a multi-exciton effect. For example, as shown in FIG. 10, when a quantum well is formed by a quantum dot and a photon having energy equal to or more than Eg_{QD} (bandgap of the quantum dot) enters the quantum dot, a photon having energy lower than that of the incident photon is discharged by allowing an electron located at a low energy level (E1) to be excited to a higher energy level (E4) and then to be dropped to a lower energy level (E3). Also, when an electron located at a lower energy level (E2) is excited to a higher energy level (E3), a photon having energy lower than that of the incident photon is discharged. In this way, two electrons having energy lower than a photon are discharged for each photon, whereby the wavelength conversion is carried out. When two electrons having energy lower than that of a photon are discharged for each photon, this is also referred to as light to light conversion. The wavelength conversion element 70 has a light to light conversion function.

In the wavelength conversion function of the wavelength conversion element 70, the wavelength to be converted and the wavelength after the conversion are appropriately selected depending on the application of the wavelength conversion element 70.

For example, when the wavelength conversion element 70 is disposed on a photoelectric conversion layer of a silicon solar cell with Eg (bandgap) of 1.2 eV, the wavelength conversion element 70 preferably has a function of wavelength-converting absorbed light into light with a wavelength of energy corresponding to the bandgap in a wavelength range of energy which is double of 1.2 eV or more (2.4 eV or more).

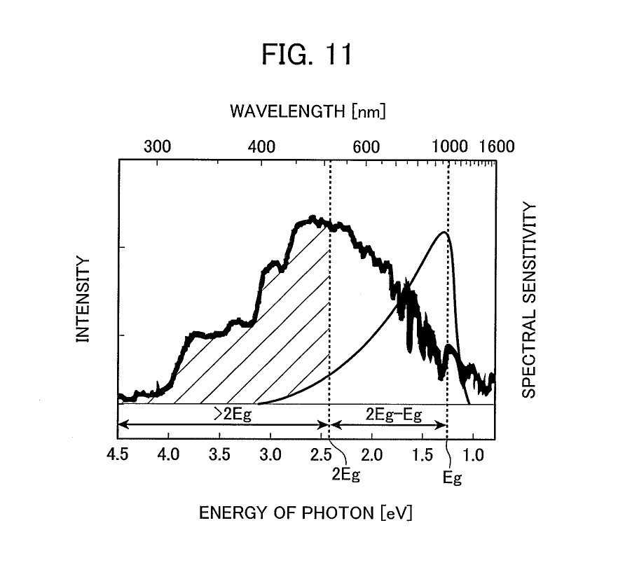

As shown in FIG. 11, comparing a sunlight spectrum with a spectral sensitivity curve of a crystalline Si, the intensity of a wavelength range corresponding to the bandgap of the crystalline Si is lower in the sunlight spectrum. Accordingly, by wavelength-converting sunlight into photons having low energy, for example, light of 1.2 eV (with a wavelength of about 1100 nm), in a wavelength range of energy which is double or more the bandgap of crystalline Si (2.4 eV or more), it is possible to supply light effective for photoelectric conversion to the photoelectric conversion layer made of crystalline Si. Thereby, it is possible to enhance the conversion efficiency of the solar cell.

As shown in FIG. 11, comparing the sunlight spectrum with the spectral sensitivity curve of crystalline Si, since the wavelength band of the bandgap of crystalline Si is narrower and the spectral sensitivity intensity of light of relatively high energy is lower in comparison with the sunlight spectrum, the sunlight is not effectively utilized. For this reason, by converting light of relatively high energy into light suitable for the spectral sensitivity of crystalline Si, it is possible to effectively utilize the sunlight. Furthermore, when light in a wavelength range of energy which is double or more the bandgap of crystalline Si, that is, a wavelength range of 2.4 eV or more, can be converted into light of two or more photons (2.4(eV)×1(photon)≈1.2(eV)×2(photons)) at the time of converting the light into light of 1.2 eV, that is, light with a wavelength of about 1100 nm, it is possible to more effectively utilize sunlight and to enhance the conversion efficiency of the solar cell. Meanwhile, in the quantum dot structure 10, as shown in FIG. 8A, light emission in the vicinity of a wavelength of 1100 nm (infrared light emission) is observed.

In the wavelength conversion element 70, the light confinement function is an anti-reflection function.

When the photoelectric conversion layer having the wavelength conversion element 70 disposed thereon is made of crystalline Si, the refractive index n_{PV} is 3.6. The refractive index nₐᵢᵣ of air in the space having them arranged therein is 1.0.

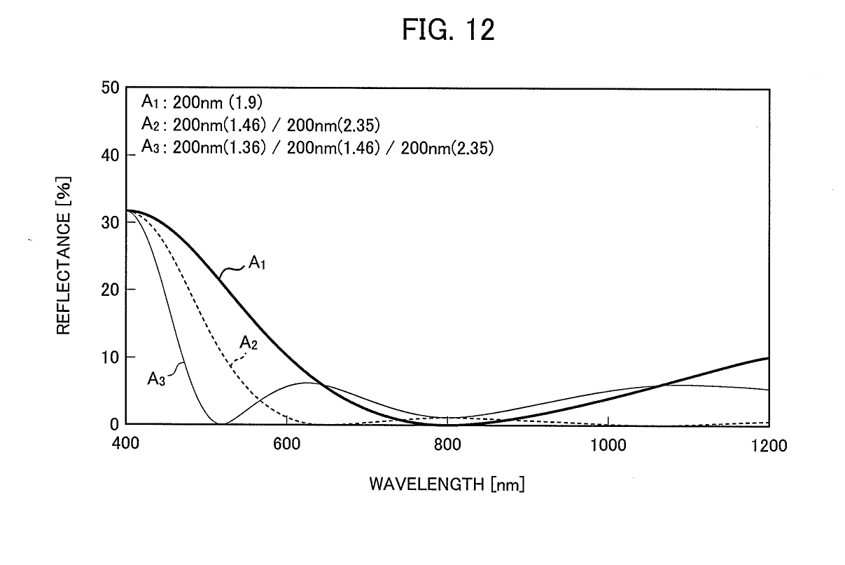

When the wavelength conversion element 70 is considered as an anti-reflection film and, for example, as shown in FIG. 12, a single-layered film with a refractive index of 1.9 (reference sign A₁), a two-layered film with refractive indices of 1.46/2.35 (reference sign A₂), and a three-layered with refractive indices of 1.36/1.46/2.35 (reference sign A₃) are compared, reflectance can be reduced in the configurations in which a film having a refractive index of 2.35 is present.

In this way, in order to cause the wavelength conversion element 70 to show the anti-reflection function, the effective refractive index n of the wavelength conversion element 70 has only to be set to a substantially intermediate refractive index between the refractive index n_{PV} of the photoelectric conversion layer (3.6 for crystalline silicon) and the refractive index of air.

In this embodiment, the effective refractive index n of the wavelength conversion element 70 (the quantum dot structure 10) is set to satisfy, for example, 1.7<n<3.0 at a wavelength of 533 nm in consideration of the application of the wavelength conversion element 70 (the quantum dot structure 10) or the like. The effective refractive index n is preferably set to satisfy 1.7<n<2.5 at a wavelength of 533 nm.

The respective quantum dots in the quantum dot structure 10 are made of a wavelength conversion composition which can wavelength-convert absorbed light in a specific wavelength range into light having energy lower than that of the absorbed light. The respective quantum dots take charge of the wavelength conversion function of the wavelength conversion element 70.

In the wavelength conversion element 70, the quantum dots are made of a material the bandgap of which is larger than the bandgap of the photoelectric conversion layer of a photoelectric conversion device having the wavelength conversion element 70 disposed thereon.

As described above, each quantum dot has a function of wavelength-converting incident light into light having energy corresponding to Eg of the photoelectric layer in a wavelength range of energy which is double or more Eg of the photoelectric conversion layer having the wavelength conversion element 70 disposed thereon. Accordingly, a material which absorbs energy double or more Eg of the photoelectric conversion layer and in which an energy level for absorbing light which is double or more the bandgap of the photoelectric conversion layer is present is selected as the material of the quantum dots.

Accordingly, a material which emits light with energy higher than Eg (bandgap) of the photoelectric conversion layer, and in which the ground level of equal to or higher than Eg of the photoelectric conversion layer is present and an energy level which is double or more Eg of the photoelectric conversion layer is present in discrete energy levels, is selected for the quantum dots.

In order to convert incident light into light which can be used in the photoelectric conversion layer, the quantum dots needs to be arranged to form an inverted population state in which the existence probability of photons which are excited from the ground level to the excited state is high. Therefore, the quantum dots are arranged in a staggered shape as described above. In this way, by biasing the particle density in a three-dimensional space, it is possible to form a spatial bias of energy and to form the inverted population state. In order to cause localization of energy, the particle diameters of the quantum dots may be made to vary. In this case, the particle diameter deviation σ_{d} (standard deviation) of the quantum dots preferably satisfies 1<σ_{d}<d/5 nm and more preferably 1<σ_{d}<d/10 nm.

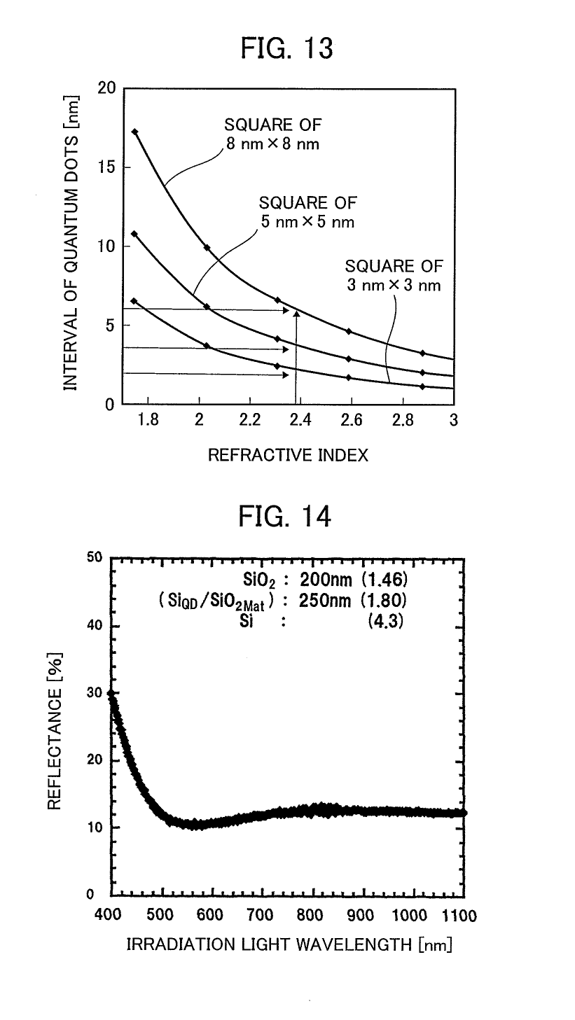

As described above, in order to achieve an anti-reflection function, the effective refractive index n of the wavelength conversion element 70 needs to be set to 2.4 which is an intermediate value between the refractive index of the photoelectric conversion layer and the refractive index of air. Therefore, the relationship between the interval of the quantum dots and the refractive index of the wavelength conversion element 70 was examined through simulation. As a result, as shown in FIG. 13, the interval of the quantum dots needs to be reduced in order to enhance the refractive index of the wavelength conversion element 70.

As shown in FIG. 13, for example, in order to set the effective refractive index n of the wavelength conversion element 70 to 2.4, it is necessary to arrange the quantum dots in the matrix layer with a small interval and with a high density. Accordingly, it is effective that the quantum dots 16 are arranged in a staggered shape like the quantum dot structure 10.

Further, the reflectance was reviewed as follows. Specifically, reflectance of a structure in which a wavelength conversion element 70 is formed on an Si substrate and an SiO₂ film is formed on the wavelength conversion element 70 was measured. In the wavelength conversion element 70, Si quantum dots are formed in an SiO₂ matrix layer (Si quantum dots/SiO_{2Mat}) and the particle diameter of the quantum dots is uniform. At this time, the refractive index of the wavelength conversion element 70 is 1.80. In this case, as shown in FIG. 14, the reflectance can be set to about 10%. The reflectance was measured using a spectral reflectometer (U4000 made by Hitachi Ltd.).

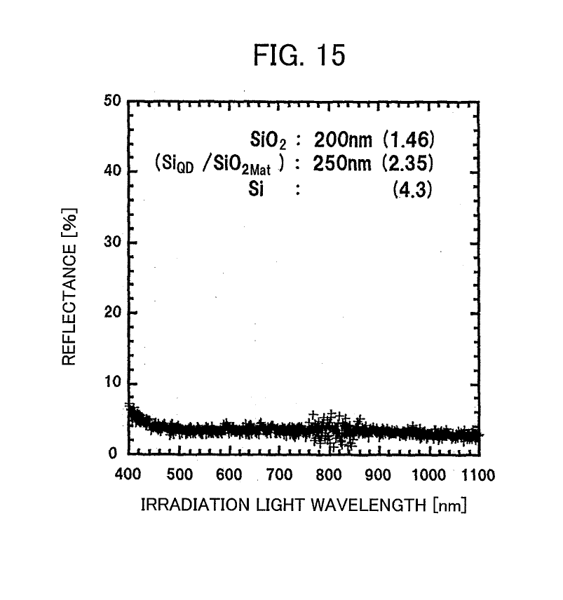

By causing the particle diameter of the quantum dots to be non-uniform, the packing factor was raised and the refractive index of the wavelength conversion element 70 was raised to 2.35. In this case, in the wavelength conversion element 70, Si quantum dots were disposed in an SiO₂ matrix layer (Si quantum dots/SiO_{2Mat}). The result is shown in FIG. 15. The reflectance was measured using a spectral reflectometer (U4000 made by Hitachi Ltd.).

In this way, by raising the filling factor of the quantum dots, it is possible to raise the refractive index and thus to lower the reflectance. Accordingly, it is possible to enhance utilization efficiency of light L which enters the wavelength conversion element 70.

The wavelength conversion element 70 according to this embodiment can be used, for example, for a solar cell as described later. Since the wavelength conversion element 70 can wavelength-convert light into light with a wavelength of 1100 nm as described above, the wavelength conversion element 70 can be used as an infrared light source. In this case, by appropriately selecting the arrangement and the composition of the quantum dots, it is possible to enhance the emission intensity of wavelength-converted light, that is, to enhance the emission intensity of infrared light.

By appropriately changing the bandgap of the quantum dots, for example, to 3.5 eV (corresponding to a wavelength of 350 nm), light can be wavelength-converted into light having energy of 1.75 eV, that is, light with a wavelength of 800 nm, and the wavelength conversion element can be used as an ultraviolet protection film.

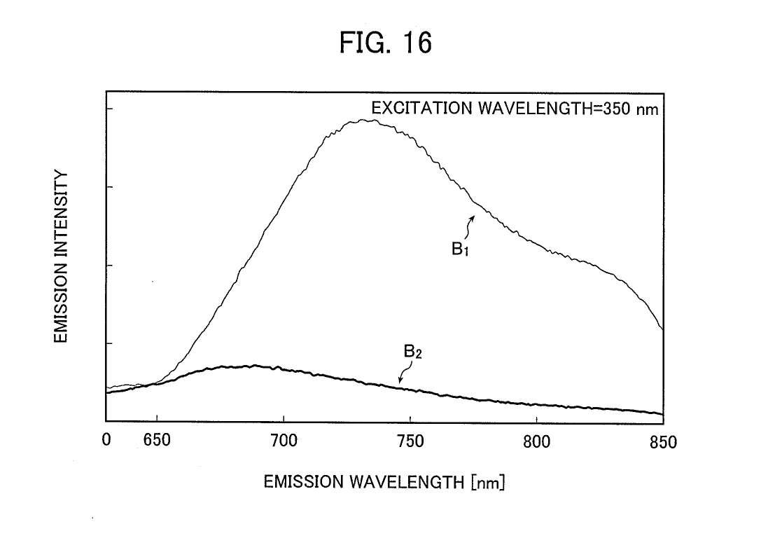

The filling factor was raised in a state where the particle diameters of the quantum dots 16 were kept uniform, whereby the effective refractive index of the wavelength conversion element 70 was raised to 2.4. The effective refractive index of the wavelength conversion element 70 with a uniform particle diameter was 1.80. By irradiating light with an excitation wavelength of 350 nm to the wavelength conversion element 70 with an effective refractive index of 2.4 and the wavelength conversion element 70 with an effective refractive index of 1.8, the emission spectra shown in FIG. 16 were obtained. In FIG. 16, reference sign B₁ represents the wavelength conversion element 70 with an effective refractive index 1.8 and reference sign B₂ represents the wavelength conversion element 70 with an effective refractive index of 2.4.

In the wavelength conversion element 70, as shown in FIG. 16, when only the refractive index is raised in a state where the particle diameters of the quantum dots 16 are kept uniform, the emission intensity becomes smaller than that of the wavelength conversion element 70 having lower refractive index. This is because when the quantum dots 16 are filled with a high density, for example, when the quantum dots are arranged with a very small interval of 5 nm or less, energy transfer is likely to occur between the quantum dots 16, and besides, when the particle diameters of the quantum dots 16 are uniform, the bias of energy is not likely to occur and energy transfer is repeated without emitting light. Accordingly, when the quantum dots 16 are uniform, the emission efficiency is lowered.

Therefore, the influence of uniformity or non-uniformity of the quantum dots on wavelength conversion was examined. A wavelength conversion element 70 was formed in which the quantum dots were uniformly arranged, the quantum dots 16 are made of Ge, the matrix layer was made of SiO₂, and the particle diameters of the quantum dots 16 were uniformly set to about 5 nm. Also, a wavelength conversion element 70 was formed in which the particle diameters of the quantum dots 16 were not uniform.

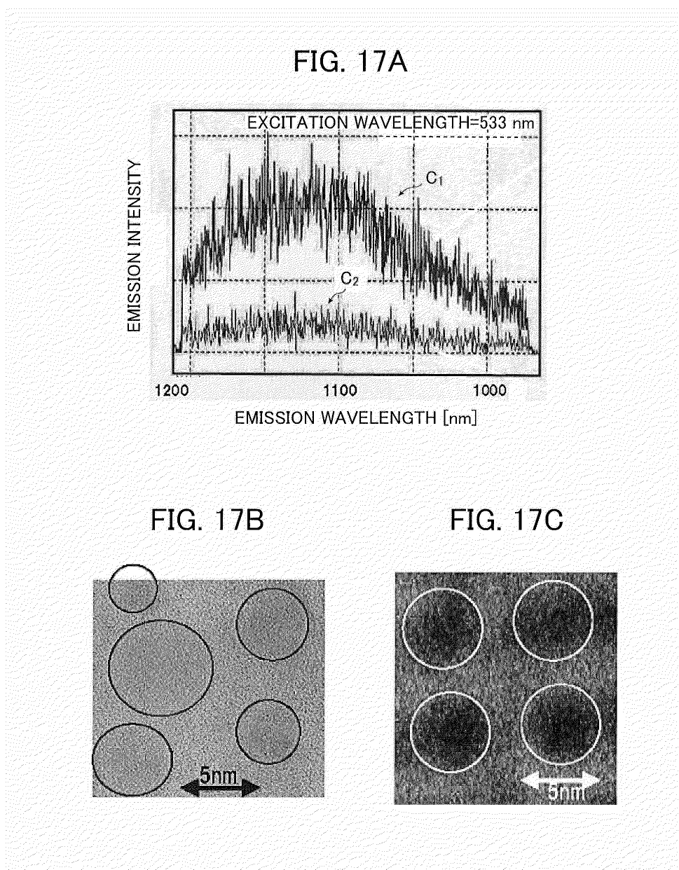

By irradiating light with an excitation wavelength of 533 nm to the wavelength conversion elements 70, emission spectra shown in FIG. 17A were obtained. In FIG. 17A, reference sign C₁ represents the emission spectrum of the wavelength conversion element 70 having non-uniform quantum dots and reference sign C₂ represents the emission spectrum of the wavelength conversion element 70 having uniform quantum dots. FIG. 17B is a drawing-substituting photograph illustrating a TEM image of the structure having non-uniform quantum dots and FIG. 17C is a drawing-substituting photograph illustrating a TEM image of the structure having uniform quantum dots.

As shown in FIG. 17A, higher emission intensity was obtained from the quantum dots with non-uniform particle diameters than from the quantum dots with uniform particle diameters. From this point, it can be seen as shown in FIGS. 16 and 17A that high emission intensity is obtained from the quantum dots with non-uniform particle diameters.

In the wavelength conversion element 70 according to this embodiment, both the wavelength conversion function and the light confinement function can be realized by the composition of four layers of the first matrix layer 14 to the fourth matrix layer 22, the composition of the quantum dots 16, and the staggered arrangement of the quantum dots 16. Accordingly, as described later, when the wavelength conversion element 70 is used for a photoelectric conversion device, light which was not utilized for photoelectric conversion in the related art can be used as light which is utilizable for photoelectric conversion to enhance utilization efficiency of incident light such as sunlight, and also reflection of light which is not wavelength-converted can be suppressed. Accordingly, it is possible to enhance conversion efficiency in the photoelectric conversion layer. Moreover, by appropriately selecting the arrangement and the composition of the quantum dots 16, it is possible to enhance the emission intensity of wavelength-converted light.

Next, a photoelectric conversion device using the wavelength conversion element 70 according to this embodiment will be described below.

The photoelectric conversion device using the wavelength conversion element 70 also functions as a light-light conversion device.

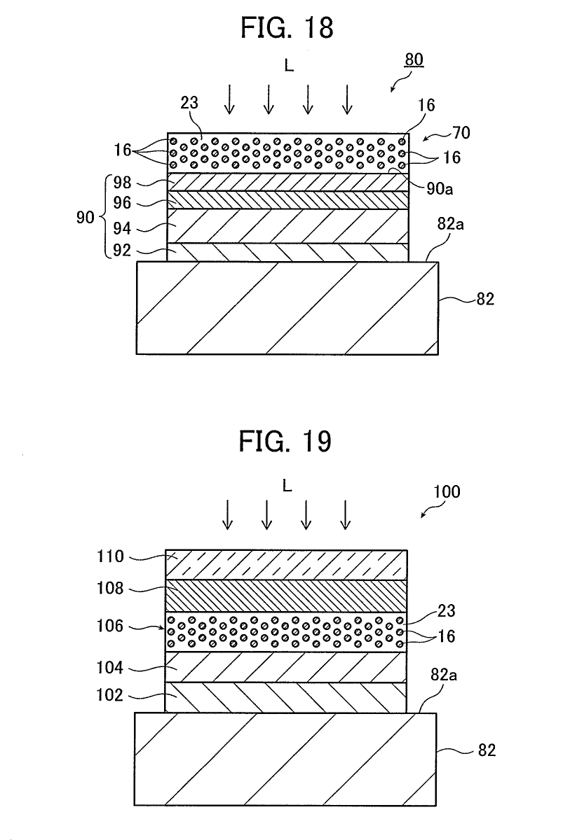

FIG. 18 is a cross-sectional view schematically illustrating a photoelectric conversion device having a wavelength conversion element according to an embodiment of the present invention.

In the photoelectric conversion device 80 shown in FIG. 18, a photoelectric conversion element 90 is provided on the surface 82a of a substrate 82. The photoelectric conversion element 90 is formed by sequentially stacking an electrode layer 92, a P-type semiconductor layer (photoelectric conversion layer) 94, an N-type semiconductor layer 96, and a transparent electrode layer 98 from the substrate 82.

The P-type semiconductor layer 94 is composed of, for example, polycrystalline silicon or monocrystalline silicon.

In this embodiment, a wavelength conversion element 70 is provided on the surface 90a of the photoelectric conversion element 90, that is, the surface of the transparent electrode layer 98.

In this case, the wavelength conversion element 70 has a wavelength conversion function of wavelength-converting incident light in a wavelength range of energy of double or more 1.2 eV which is the band gap of Si constituting the P-type semiconductor layer 94 into light having energy of 1.2 eV corresponding to the bandgap of Si which is a half of the incident light, that is, light with a wavelength of 533 nm. Further, the effective refractive index of the wavelength conversion element 70 is an intermediate refractive index between the refractive index of Si and the refractive index of air.

Accordingly, since reflected light decreases and the light intensity at a wavelength utilizable for photoelectric conversion increases by wavelength-converting light of a specific wavelength range not contributing to the photoelectric conversion, it is possible to improve the conversion efficiency of the photoelectric conversion element 90 and to enhance power generation efficiency of the photoelectric conversion device 80 as a whole.

When polycrystalline silicon is used for the P-type semiconductor layer 94 (photoelectric conversion layer) of the photoelectric conversion element 90, various plane orientations appear and thus reflectance is not uniform. Accordingly, even when an anti-reflection film effective in a certain plane orientation is formed, the anti-reflection effect is not effective in the entire photoelectric conversion layer. However, the wavelength conversion element 70 can improve transmission characteristics of a specific wavelength range so as to keep reflection loss low. From this point, it is possible to improve the power generation efficiency of the photoelectric conversion device 80 as a whole.

When it is intended to provide the wavelength conversion element 70, the wavelength conversion element 70 can be simply disposed on the surface 90a of the photoelectric conversion element 90 and etching or the like is not necessary. Accordingly, the photoelectric conversion device is not damaged by the etching or the like. As a result, it is possible to suppress occurrence of manufacturing defects.

In the present invention, the photoelectric conversion layer is not limited to use silicon, and the photoelectric conversion layer may be a CIGS-based photoelectric conversion layer, a CIS-based photoelectric conversion layer, CdTe-based photoelectric conversion layer, a dye-sensitized photoelectric conversion layer, or an organic photoelectric conversion layer.

The substrate 82 should have relatively high heat resistance. For example, a glass substrate such as a blue plate glass or the like, a heat-resistant glass substrate, a quartz substrate, a stainless steel substrate, a metal multi-layered substrate in which stainless steel and dissimilar metal are laminated, an aluminum substrate, an aluminum substrate with an oxide film in which the surface insulation is improved by performing an oxidation treatment such as an anodization on the surface, or the like can be used as the substrate 82.

Another photoelectric conversion device using a quantum dot structure will be described below.

A photoelectric conversion device 100 (solar cell) according to this embodiment shown in FIG. 19 includes a substrate 82, an electrode layer 102, a P-type semiconductor layer 104, a photoelectric conversion layer 106, an N-type semiconductor layer 108, and a transparent electrode layer 110, and is called a substrate type.

In the photoelectric conversion device 100, a stacked structure in which the electrode layer 102, the P-type semiconductor layer 104, the photoelectric conversion layer 106, the N-type semiconductor layer 108, and the transparent electrode layer 110 are stacked is formed on the surface 82a of the substrate 82. That is, in the photoelectric conversion device 100, the N-type semiconductor layer 108 is provided on one side of the photoelectric conversion layer 106, and the P-type semiconductor layer 104 is provided on the other side thereof. The electrode layer 102 is provided on the side of the P-type semiconductor layer 104 opposite to the photoelectric conversion layer 106. The transparent electrode layer 110 is provided on the side of the N-type semiconductor layer 108 opposite to the photoelectric conversion layer 106. The photoelectric conversion layer 106 is composed of the quantum dot structure 10. The matrix of the photoelectric conversion layer 106 is made of an amorphous nitride semiconductor similarly to the matrix layer of the above-mentioned quantum dot structure. Examples of the nitride semiconductor include GaN, SiNy, AlN, and InGaN.

The substrate 82 has the same configuration as the photoelectric conversion device 80 shown in FIG. 18 and thus detailed description thereof will not be repeated.

The electrode layer 102 is provided on the surface 82a of the substrate 82 and serves to extract current obtained by the photoelectric conversion layer 106 to the outside in cooperation with the transparent electrode layer 110. For example, Mo, Cu, Cu/Cr/Mo, Cu/Cr/Ti, Cu/Cr/Cu, Ni/Cr/Au, or the like can be used in the electrode layer 102.

When the electrode layer 102 comes in contact with the N-type semiconductor layer, for example, Nb-doped Mo, Ti/Au, or the like can be used in the electrode layer 102.

The P-type semiconductor layer 104 is provided on the electrode layer 102 so as to come in contact with the photoelectric conversion layer 106. The P-type semiconductor layer 104 is made of, for example, a material having bandgap equal to or larger than the bandgap of GaN, SiNy, AlN, or InGaN which constitutes the matrix of the photoelectric conversion layer 106 (the matrix layer of the quantum dot structure) to be described later. Mn-doped GaN, B-doped SiC, CuAlS₂, CuGaS, or the like can also be used in the P-type semiconductor layer 104.

The N-type semiconductor layer 108 has the same composition as the matrix of the photoelectric conversion layer 106 (the matrix layer of the quantum dot structure). That is, the N-type semiconductor layer is made of GaN, SiNy, AlN, or InGaN.

The transparent electrode layer 110 serves to extract current obtained by the photoelectric conversion layer 106 to the outside in cooperation with the electrode layer 102 and is provided on the entire surface of the N-type semiconductor layer 108. The transparent electrode layer 110 may be provided on a part of the N-type semiconductor layer 108. In the photoelectric conversion device 100, light L enters from the transparent electrode layer 110.

The transparent electrode layer 110 is made of a material having N-type conductivity. Examples of the material of the transparent electrode layer 110 include Ga₂O₃, SnO₂-based material (for example, ATO (Antimony Tin Oxide), and FTO (Fluorine-doped Tin Oxide)), ZnO-based material (for example, AZO (Al-doped Zinc Oxide), and GZO (Gallium-doped Zinc Oxide)), In₂O₃-based material (for example, ITO (Indium Tin Oxide)), Zn(O,S)CdO, or alloys of two or three kinds of these materials. In addition, MgIn₂O₄, GaInO₃, CdSb₃O₆, or the like may be used in the transparent electrode layer 110.

In this embodiment, the thickness of the P-type semiconductor layer 104 and the N-type semiconductor layer 108 is, for example, in a range of 50 to 300 nm and preferably 100 nm.

In this embodiment, the electron mobility of the P-type semiconductor layer 104 and the electron mobility of the N-type semiconductor layer 108 are, for example, in a range of 0.01 to 100 cm²/Vsec and preferably in a range of 1 to 100 cm²/Vsec.

In the photoelectric conversion layer 106, the quantum dots 16 are arranged in the same staggered shape as the quantum dot structure 10 and are three-dimensionally uniformly distributed and arranged at regular intervals so as to superimpose plural wave functions to form a miniband between the neighboring quantum dots 16.

Specifically, the interval of the quantum dots 16 is 10 nm or less and preferably in a range of 2 to 6 nm.

The average particle diameter of the quantum dots 16 is, for example, in a range of 2 to 12 nm and preferably in a range of 2 to 6 nm. It is preferable that the deviation in particle diameter of the quantum dots 16 be ±20% or less.

By constituting and arranging the quantum dots 16 in this way, the tunneling probability between the quantum wells formed by the quantum dots 16 increases and plural wave functions are superimposed to form a miniband, whereby it is possible to reduce loss due to carrier transport and to raise the moving speed of electrons between the quantum wells, that is, between the quantum dots 16.

In the photoelectric conversion layer 106, the matrix layer 23 containing the quantum dots 16 has the same configuration as in the photoelectric conversion device 80 shown in FIG. 18 and thus detailed description thereof will not be repeated. The thickness of the matrix layer 23 is, for example, in a range of 200 to 800 nm and preferably 400 nm.

The present invention basically has the above-mentioned configuration. While the quantum dot structure and the quantum dot structure forming method according to the present invention have been described in detail, the present invention is not limited to the above-mentioned embodiments, and of course, various improvements and modification may be made without departing from the gist of the present invention.

### Example 1

In this example, films were formed under the following film forming conditions using a general-use RF sputtering method which can form a film with a large area at a high speed without using relatively expensive equipment.

A SiNy film was used as the matrix layer, InNx was used for the particulates to be quantum dots (QD made of InN), and the SiNy film and the InNx film were alternately stacked on an Si substrate with design thicknesses of 20 nm and 10 nm under the following conditions.

Regarding the conditions for forming the SiNy film, Si₃N₄ was used as a target, an ultimate vacuum was set to 3×10⁻⁴ Pa or less, the substrate temperature was set to the RT, the input power was set to 100 W, the film forming pressure was set to 0.3 Pa, the flow rate of argon gas as the sputtering gas was set to 15 sccm, and the flow rate of nitrogen gas as the reactant gas was set to 5 sccm.

Regarding the conditions for forming the InN film, In was used as a target, an ultimate vacuum was set to 3×10⁻⁴ Pa or less, the substrate temperature was set to the RT, the input power was set to 30 W, the film forming pressure was set to 0.1 Pa, the flow rate of argon gas as the sputtering gas was set to 3 sccm, and the flow rate of nitrogen gas as the reactant gas was set to 5 sccm.

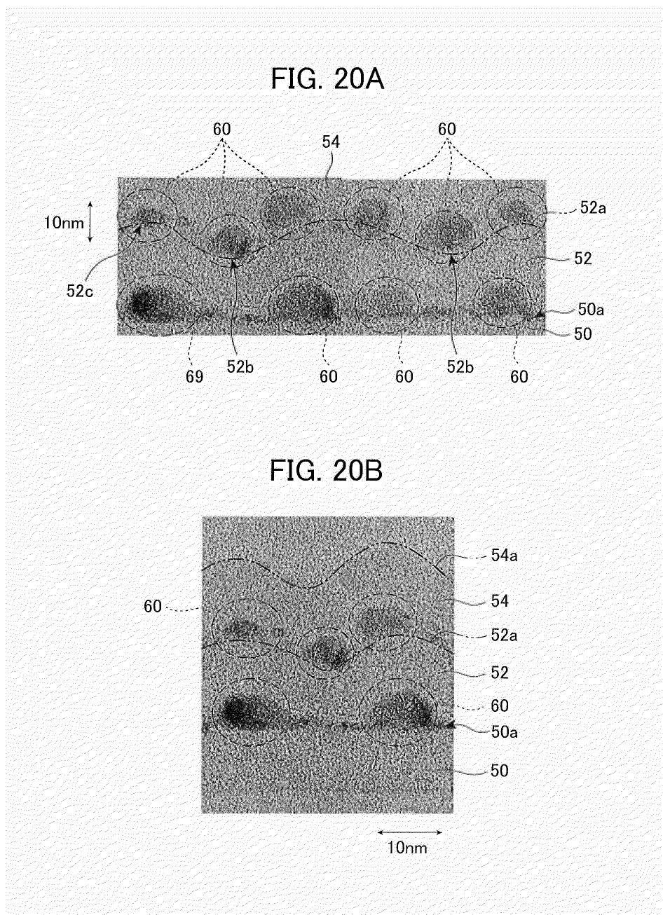

As a result, as shown in FIG. 20A, particulates 60 made of InNx of the first layer are discretely and periodically formed on the surface 50a of the Si substrate 50. A first matrix layer 52 is formed on the surface 50a of the Si substrate 50 so as to cover the particulates 60. The surface 52a of the first matrix layer 52 has a concavo-convex shape reflecting unevenness due to the shape and the arrangement state of the particulates 60 of the first layer. The particulates 60 are selectively formed at the concave portions 52b and the convex portions 52c of the surface 52a of the first matrix layer 52, and the particulates 60 are not formed at the intermediate portions between the concave portions 52b and the convex portions 52c. In this way, when the InNx film is formed under the above-mentioned conditions, particulates 60 having a spherical shape are discretely and periodically formed.

Even when the matrix layer is formed to cover the particulates 60, the periodicity of the unevenness on the surface of the underlying matrix layer can be maintained. Specifically, as shown in FIG. 20B, the SiNy film constituting the matrix layer reflects the unevenness formed due to the shape and the arrangement state of the particulates 60, and the surface 52a of the first matrix layer 52 and the surface 54a of the second matrix layer 54 have the same periodicity of unevenness maintained.

It was confirmed that in order to maintain the periodicity of unevenness, the atomic % ratio of In and N at the time of forming the particulates 60 should satisfy 65:35≦In:N≦8:2. Moreover, it could be confirmed that the layers can be crystallized in the state where the periodicity of unevenness is maintained by performing an annealing treatment in the state where the periodicity of unevenness is maintained.

A SiNy film was used as the matrix layer, InNx was used for the particulates to be quantum dots (QD made of InN), the SiNy film and the InNx film were alternately stacked on an Si substrate with design thicknesses of 5 nm and 5 nm under the following conditions, and then the resultant was annealed at a temperature of 460° C.

Regarding the conditions for forming the SiNy film, Si₃N₄ was used as a target, an ultimate vacuum was set to 3×10⁻⁴ Pa or less, the substrate temperature was set to the RT, the input power was set to 100 W, the film forming pressure was set to 0.3 Pa, the flow rate of argon gas as the sputtering gas was set to 15 sccm, and the flow rate of nitrogen gas as the reactant gas was set to 5 sccm.

Regarding the conditions for forming the InN film, In was used as a target, an ultimate vacuum was set to 3×10⁻⁴ Pa or less, the substrate temperature was set to the RT, the input power was set to 45 W, the film forming pressure was set to 0.1 Pa, the flow rate of argon gas as the sputtering gas was set to 8 sccm, and the flow rate of nitrogen gas as the reactant gas was set to 10 sccm.

When the SiNy film and the InNx film were stacked under the above-mentioned conditions, a layered structure in which the InNx film made of InNx is present between the matrix layers (SiNy films) was obtained. By performing an annealing treatment in a state where the periodicity of the layered structure is maintained, spherical particulates having a crystal shape were formed discretely and periodically.

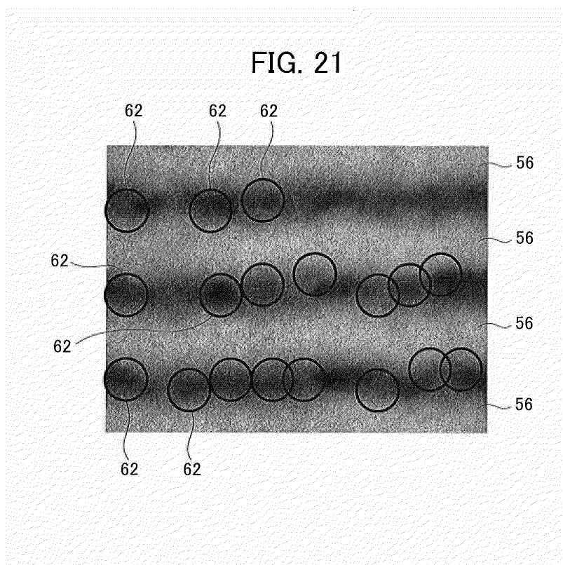

As a result, a layered structure in which crystalline quantum dots 62 made of InNx are formed between the matrix layers 56 was obtained as shown in FIG. 21. In order to obtain the above-mentioned layered structure, it was confirmed that the atomic % ratio of In and N at the time of forming the particulates to be the quantum dots 62 satisfies 50:50≦In:N≦65:35.

What is claimed is:

1. A quantum dot structure forming method of forming crystalline quantum dots in a matrix layer on a substrate by supplying sputtering gas and reactant gas to a chamber in which the substrate and a target are disposed and performing a sputtering, wherein the matrix layer is made of a dielectric or a first nitride semiconductor, the quantum dots are made of a second nitride semiconductor, and the dielectric or the first nitride semiconductor and the second nitride semiconductor is different in composition from each other, the quantum dot structure forming method comprising the steps of:
performing a sputtering using a constituent metal element of the second nitride semiconductor constituting the quantum dots as the target and using nitrogen gas as the reactant gas to periodically deposit particulates on the substrate with substantially the same size as the quantum dots in an amorphous state in which a nitrogen ratio is lower than a stoichiometric ratio;
forming the matrix layer made of the dielectric or the first nitride semiconductor with a uniform thickness so as to cover the particulates; and
alternately repeating the step of depositing the particulates and the step of forming the matrix layer to stack the matrix layer having the particulates therein and form a layered structure, and crystallizing the particulates to form the quantum dots by subjecting the layered structure to a heat treatment in an atmosphere of inert gas.

2. The quantum dot structure forming method according to claim 1, wherein in the step of forming the matrix layer, the surface of the matrix layer has a concavo-convex shape which reflects the shapes of the particulates and has a periodic unevenness with substantially the same size as the quantum dots, and
wherein particulates to be formed on the surface of the matrix layer are selectively formed at concave portions and convex portions of the concavo-convex shape.

3. The quantum dot structure forming method according to claim 1, wherein the particulates formed in the step of depositing the particulates are particulates of InNx having an atomic % ratio of In and N in a range of In:N=8:2 to In:N=65:35.

4. The quantum dot structure forming method according to claim 1, wherein the heat treatment of crystallizing the particulates to form the quantum dots is performed under conditions of an atmosphere of nitrogen-containing gas, a temperature of 500° C. or lower, and a retention time of 30 minutes or less.

5. The quantum dot structure forming method according to claim 1, wherein melting points of the dielectric or the first nitride semiconductor and the second nitride semiconductor satisfy the second nitride semiconductor<the dielectric or the first nitride semiconductor.

6. The quantum dot structure forming method according to claim 1, wherein melting points of the dielectric or the first nitride semiconductor and the second nitride semiconductor satisfy the second nitride semiconductor<500° C.<the dielectric or an alloy of the first nitride semiconductor and the second nitride semiconductor.

7. The quantum dot structure forming method according to claim 1, wherein the first nitride semiconductor constituting the matrix layer is GaN, SiNy, AlN, or InGaN.

8. A quantum dot structure comprising:
a matrix layer; and
a plurality of crystalline quantum dots that are disposed discretely in the matrix layer,
wherein the quantum dots are disposed at different positions in a thickness direction of the matrix layer.

9. The quantum dot structure according to claim 8, wherein a plurality of the matrix layers are formed, a surface of an underlying matrix layer has a concavo-convex shape which reflects shapes of the quantum dots and has a periodic unevenness with substantially the same size as the quantum dots, and the quantum dots are selectively formed at concave portions and convex portions of the surface.

10. The quantum dot structure according to claim 8, wherein the matrix layer is made of a dielectric or a first nitride semiconductor, the quantum dots are made of a second nitride semiconductor, and the dielectric or the first nitride semiconductor and the second nitride semiconductor are different in composition from each other, and
wherein melting points of the dielectric or the first nitride semiconductor and the second nitride semiconductor satisfy the second nitride semiconductor<the dielectric or the first nitride semiconductor.

11. The quantum dot structure according to claim 8, wherein melting points of the dielectric or the first nitride semiconductor and the second nitride semiconductor satisfy the second nitride semiconductor<500° C.<the dielectric or an alloy of the first nitride semiconductor and the second nitride semiconductor.

12. The quantum dot structure according to claim 8, wherein the second nitride semiconductor constituting the quantum dots is InN, and the first nitride semiconductor constituting the matrix layer is GaN, SiNy, AlN, or InGaN.

13. A wavelength conversion element including the quantum dot structure according to claim 8 and a wavelength conversion layer having a function of improving transmittance of an arbitrary wavelength range,
wherein the quantum dots are made of a wavelength conversion composition that wavelength-converts absorbed light into light having energy lower than that of the absorbed light in a specific wavelength range of the absorbed light.

14. A light-light conversion device, wherein the wavelength conversion element according to claim 13 is disposed on an incidence side of a photoelectric conversion layer, and
wherein an effective refractive index of the wavelength conversion element is an intermediate refractive index between a refractive index of the photoelectric conversion layer and a refractive index of air.

15. A photoelectric conversion device, wherein an N-type semiconductor layer is disposed on one side of a photoelectric conversion layer having the quantum dot structure according to claim 8 and a P-type semiconductor layer is disposed on the other side thereof, and
wherein the quantum dots are three-dimensionally uniformly distributed and are arranged at regular intervals so as to superimpose a plurality of wave functions to form a miniband between the neighboring quantum dots.
